(19) United States
(12) Patent Application Publication
(10) Pub. No.: US 2007/0172995 A1
(43) Pub. Date: Jul. 26, 2007

(54) Method for forming fuse of semiconductor device

(75) Inventor: Ki Soo Choi, Chungcheongbuk-do (KR)

Correspondence Address: HELLER EHRMAN LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/474,952

(22) Filed: Jun. 27, 2006

(30) Foreign Application Priority Data
Jan. 23, 2006 (KR) 10-2006-0006961

(51) Int. Cl. H01L 21/82

(52) U.S. Cl. 438/132

(57) ABSTRACT

A method for forming a fuse of a semiconductor device by forming a plate layer wherein a predetermined portion of the plate layer is cut by etching; forming an interlayer insulating film over the plate layer; forming a plate layer contact which is connected to the plate layer through the interlayer insulating film; forming a metal wired layer and a fuse layer that contacts the plate layer contact over the interlayer insulating film; etching the top portion of the fuse layer; and forming a passivation layer on the entire surface of the resultant structure. A protective layer is formed over a metal fuse layer to protect damage of peripheral regions due to scattered reflection in a repair mode.

### BACKGROUND OF THE INVENTION

1. Field of the Invention

The present invention generally relates to a method for forming a fuse of a semiconductor device, and more specifically, to a method for forming a fuse of a semiconductor device that includes forming a protective layer over a metal fuse layer to prevent damage of peripheral regions due to scattered reflection in a repair mode.

2. Description of the Related Art

When even one of the memory cells has a defect in the fabrication of a memory device, the memory device does not properly operate so that it is regarded as being defective.

However, it is ineffective to discard the whole memory device when a part of the cells in the memory have a defect.

As a result, the defective cell is replaced with a redundancy cell which is previously installed in the memory device to repair the whole memory, thereby improving yield.

The repair operation with a redundancy cell is performed by substituting a defective memory cell with a spare memory cell positioned at a spare row and a spare column in each cell array.

More specifically, after the wafer processing is finished, a test is performed on an internal circuit to select a defective memory cell and replace the corresponding address with an address signal of the spare cell.

When an address signal corresponding to a defective line is inputted, the defective line is substituted by a redundancy line.

One of these program methods is to disconnect a fuse with laser beam. A wire disconnected by radiation of the laser is referred to as a fuse line, and the disconnected site and its surrounding region are referred as to a fuse box.

But the conventional method for forming the fuse has the following shortcomings.

First, the etching amount for the fuse opening becomes excessive when the fuse layer is formed as a bottom layer such as a gate layer or a bit line. As a result, the uniformity degrades due to excessive etching amount, and also the defective ratio of fuse cutting increases due to control degradation of residual oxide films of the top portion of the fuse.

When a bit line is used as a fuse layer, defects are generated by oxidation due to moisture absorption. In order to prevent generation of the defects, a protective layer for preventing moisture absorption is required after fuse open etching, which makes fabrication difficult and increases cost.

If a top barrier layer of the fuse layer is etched when a metal layer is used as a fuse layer, a step difference between the metal layer and the peripheral oxide films and scattered reflection of laser wavelength in the laser repair mode are generated, which damages the peripheral fuse layers.

### SUMMARY OF THE INVENTION

Various embodiments are directed at preventing blowing defects and cracks in fuse formation and also forming a protective layer over a metal fuse layer to prevent damage of peripheral regions due to scattered reflection in the repair mode.

According to an embodiment of the present invention, a method for forming a fuse of a semiconductor device comprises: forming a plate layer wherein a predetermined portion of the plate layer is cut by etching; forming an interlayer insulating film over the plate layer; forming a plate layer contact which is connected to the plate layer through the interlayer insulating film; forming a metal wired layer and a fuse layer that contacts the plate layer contact over the interlayer insulating film; etching the top portion of the fuse layer; and forming a passivation layer on the entire surface of the resultant structure.

### BRIEF DESCRIPTION OF THE DRAWINGS

Other aspects and advantages of the present invention will become apparent upon reading the following detailed description and upon reference to the drawings in which:

FIG. 1 is a cross-sectional diagram illustrating a fuse box of a semiconductor device according to an embodiment of the present invention;

FIG. 2 is a plane diagram illustrating a fuse box of a semiconductor device according to an embodiment of the present invention; and

FIGS. 3a through 3c are expanded diagrams illustrating a fuse layer according to an embodiment of the present invention.

### DETAILED DESCRIPTION OF THE EXAMPLARY EMBODIMENTS

The present invention will be described in detail with reference to the accompanying drawings. Wherever possible, the same reference numbers will be used throughout the drawings to refer to the same or like parts.

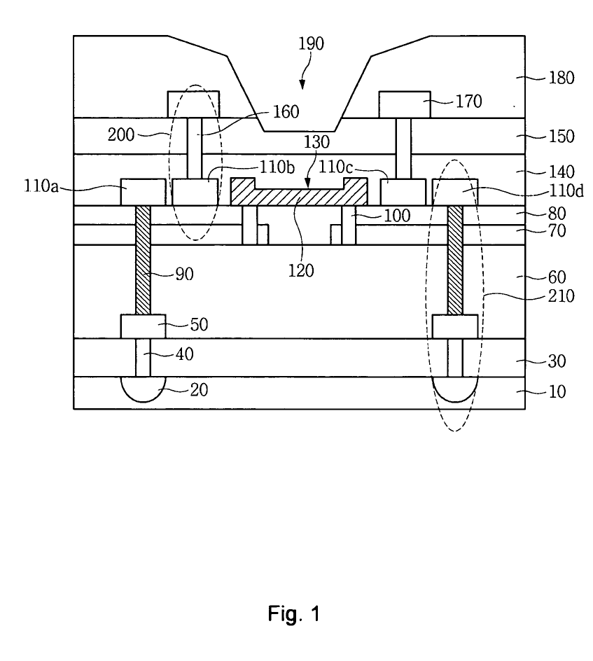

FIG. 1 is a cross-sectional diagram illustrating a fuse box of a semiconductor device according to an embodiment of the present invention.

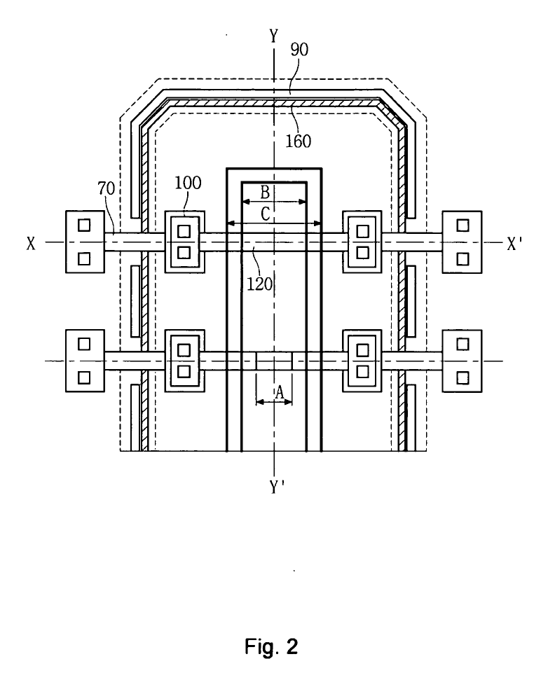

FIG. 2 is a plane diagram illustrating a fuse box of a semiconductor device according to an embodiment of the present invention.

FIG. 1 is cross-sectional diagram of the X-X′ axis direction of FIG. 2.

Referring to FIG. 1, an active region (source/drain region) 20 is formed over a semiconductor substrate 10.

A first interlayer insulating film 30 is formed over the semiconductor substrate 10.

A bit line contact 40 is formed which is connected to the active region 20 through the first interlayer insulating film 30.

A bit line 50 connected to the bit line contact 40 is formed over the first interlayer insulating film 30.

A second interlayer insulating film 60 is formed over the bit line 50.

A plate layer 70 is formed over the second interlayer insulating film 60. A predetermined portion of the plate layer 70 is cut by etching.

A third interlayer insulating film 80 is formed over the plate layer 70.

A first metal contact 90 is formed which is connected to the bit line 50 through the second interlayer insulating film 60 and the third interlayer insulating film 80.

A plate layer contact 100 is formed which is connected to the plate layer 70 through the third interlayer insulating film 80.

First metal wired layers 110a, 110b, 110c, 110d and a fuse layer 120 which contacts with the plate layer contact 100 are formed over the third interlayer insulating film 80. The fuse layer 120 is connected to a peripheral circuit unit through the plate layer contact 100 and the plate layer 70.

A top portion 130 of the fuse layer 120 is etched with a fuse mask for blowing improvement. Preferably, the top portion 130 of the fuse layer 120 is etched to have a concavo-concave shape.

A first passivation layer 140 is formed over the fuse layer 120.

A fourth interlayer insulating film 150 is formed over the first passivation layer 140.

A second metal contact 160 is formed which is connected to the first metal wired layer 110 through the first passivation layer 140 and the fourth interlayer insulating film 150.

A second metal wired layer 170 is formed over the fourth interlayer insulating film 150.

A second passivation layer 180 is formed over the second metal wired layer 170.

The second passivation layer 180 and the fourth interlayer insulating film 150 are etched with a repair mask to form a fuse open unit 190.

The first metal wired layer 110b and 110c, the second metal contact 160 and the second metal wired layer 170 form a first guard ring structure 200. The active region 20, the bit line contact 40, the bit line 50, the first metal contact 90 and the first metal wired layers 110a and 110d form a second guard ring structure 210.

The first guard ring structure 200 and the second guard ring structure 210 protect the peripheral circuit unit from oxidation due to moisture absorption.

Referring to FIG. 2, the circumference of the fuse layer 120 is surrounded by the first guard ring structure 160 and the second guard ring structure 90.

The plate layer contact 100 is formed which connects the plate layer 70 to both ends of the fuse layer 120.

The plate layer 70 is connected to the peripheral circuit unit through a pad.

The blowing size A is smaller than the size B of the repair mask that is smaller than the size C of the fuse mask.

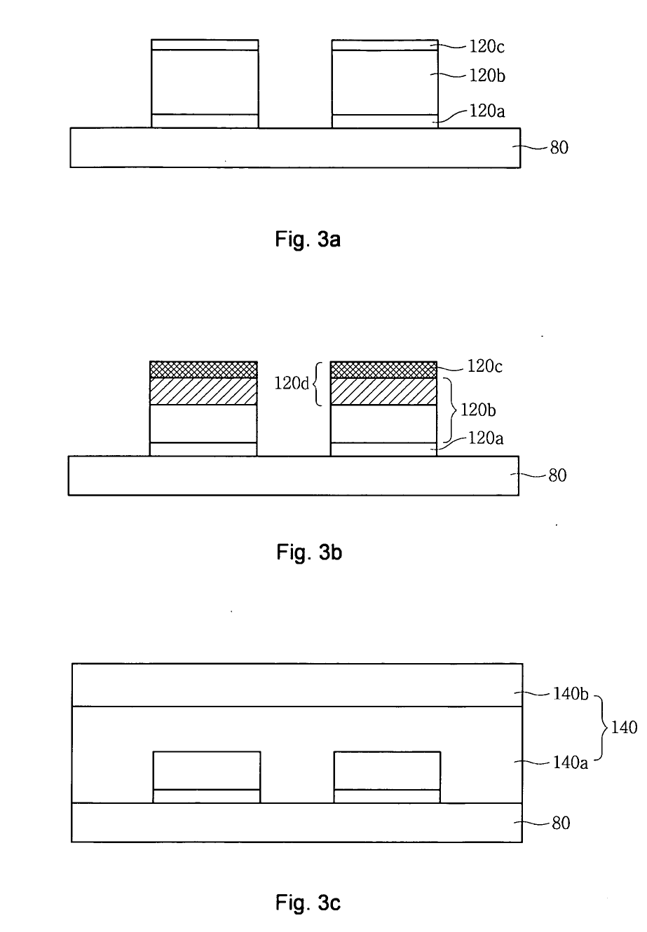

FIGS. 3a through 3c are expanded diagrams illustrating the fuse layer 120 according to an embodiment of the present invention. FIGS. 3a through 3c are cross-sectional diagrams of the Y-Y′ axis direction of FIG. 2.

Referring to FIGS. 3a through 3c, the forming step of the fuse layer 120, the etching step of the top portion of the fuse layer 120 with the fuse mask and the forming step of the first passivation layer 140 are explained in detail.

Referring to FIG. 3a, a bottom barrier layer 120a, a metal layer 120b and a top barrier layer 120c are sequentially formed.

The bottom barrier layer 120a is formed of Ti or TiN.

The metal layer 120b is formed by one selected from conductive materials such as tungsten W, aluminum Al and copper Cu, mixtures thereof or alloys thereof.

Referring to FIG. 3b, the entire portion of the top barrier layer 120c and the partial portion of the metal layer 120b are etched for blowing improvement (120d). Here, the entire portion of the top barrier layer 120c and the metal layer 120b can be etched. When the entire portion of the top barrier layer 120c and the metal layer 120b is etched, the thickness of the bottom barrier layer 120a may be adjustable under consideration of loss due to dry etching.

Referring to FIG. 3c, the first passivation layer 140 is formed.

The first passivation layer 140 is obtained by sequentially depositing a layer (not shown) for protecting the metal layer 120b, an insulating film 140a for gap-fill and an etching barrier layer 140b.

When the metal layer 120b is formed of Al, the layer for protecting the metal layer 120b can be Al₂O₃.

The insulating film 140a for gap-fill can be formed of BPSG (boron phosphorous silicate glass) or SOG (spin on glass).

The etching barrier layer 140b is used for control of a residual oxide film between the fuse layer 120 and the fuse open unit 190.

As described above, a method for forming a fuse of a semiconductor device according to an embodiment of the present invention protects blowing defects and cracks and also prevents damage of peripheral regions due to scattered reflection in a repair mode by forming a protective layer over a metal fuse layer.

The foregoing description of various embodiments of the invention has been presented for purposes of illustration and description. It is not intended to be exhaustive or to limit the invention to the precise form disclosed, and modifications and variations are possible in light of the above teachings or may be acquired from practice of the invention. Thus, the embodiments were chosen and described in order to explain the principles of the invention and its practical application to enable one skilled in the art to utilize the invention in various embodiments and with various modifications as are suited to the particular use contemplated.

What is claimed is:

1. A method for forming a fuse of a semiconductor device, the method comprising:
forming a plate layer wherein a predetermined portion of the plate layer is cut by etching;
forming an interlayer insulating film over the plate layer;
forming a plate layer contact, the plate layer contact being connected to the plate layer through the interlayer insulating film;
forming a metal wired layer and a fuse layer, the fuse layer contacting the plate layer contact over the interlayer insulating film;
etching the top portion of the fuse layer; and
forming a passivation layer on the entire surface of the resultant structure.

2. The method according to claim 1, wherein the fuse layer has a deposition structure including a lower barrier layer, a metal layer and an upper barrier layer.

3. The method according to claim 2, wherein the etching step of the top portion of the fuse layer includes etching the entire portion of the upper barrier layer and the partial portion of the metal layer.

4. The method according to claim 2, wherein the etching step of the top portion of the fuse layer includes etching the entire portion of the upper barrier layer and the metal layer.

5. The method according to claim 2, wherein the passivation layer has a deposition structure including a layer for protecting the metal layer, an insulating film for gap-fill and an etching barrier layer.

6. The method according to claim 1, further comprising before the forming step of the plate layer:
forming an active region over a semiconductor substrate;
forming a first interlayer insulating film over the semiconductor substrate;
forming a bit line contact connected to the active region through the first interlayer insulating film;
forming a bit line connected to the bit line contact over the first interlayer insulating film; and
forming a second interlayer insulating film over the bit line.

7. The method according to claim 6, further comprising after the interlayer insulating film is formed over the plate layer:
forming a first metal contact, the first metal contact connecting the bit line to the metal wired layer through the second interlayer insulating film and the interlayer insulating film.

8. The method according to claim 7, wherein the active region, the bit line contact, the bit line, the first metal contact and the metal wired layer form a guard ring structure.

9. The method according to claim 1, further comprising:
forming a fourth insulating film over the passivation layer;
forming a second metal contact connected to the metal wired layer through the passivation layer and the fourth interlayer insulating film; and
forming a second metal wired layer over the fourth interlayer insulating film.

10. The method according to claim 9, wherein the metal wired layer, the second metal contact and the second metal wired layer form a guard ring structure.

11. The method according to claim 1, wherein the etching step of the top portion of the fuse layer includes etching the fuse layer to have a concavo-concave shape.
